(19) United States
(12) Patent Application Publication
(10) Pub. No.: US 2026/0271549 A1
(43) Pub. Date: Sep. 10, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-si (KR)

(72) Inventors: KYEUK LEE, Yongin-si (KR); SEONGYOUNG LEE, Yongin-si (KR); JIN-WON LEE, Yongin-si (KR); JIYUN HONG, Yongin-si (KR)

(21) Appl. No.: 19/390,309

(22) Filed: Nov. 14, 2025

(30) Foreign Application Priority Data
Mar. 10, 2025 (KR) 10-2025-0030872

(51) Int. Cl. H10K 59/123; H10K 59/12; H10K 59/121

(52) U.S. Cl. CPC H10K 59/123; H10K 59/1201; H10K 59/1213

(57) ABSTRACT

A display device includes: a substrate comprising a display area; a thin-film transistor on the display area; a first insulating layer on the thin-film transistor and comprising a through hole exposing a source electrode or a drain electrode of the thin-film transistor; a second insulating layer on the first insulating layer and comprising a first via hole and a second via hole which are spaced apart from each other; and a pixel electrode on the second insulating layer and electrically connected to the thin-film transistor via the through hole, wherein the first via hole overlaps the through hole, and the second via hole does not overlap the through hole.

### CROSS-REFERENCE TO RELATED APPLICATION

The present application claims priority to and the benefit of Korean Patent Application No. 10-2025-0030872, filed on Mar. 10, 2025, in the Korean Intellectual Property Office, the entire disclosure of which is incorporated herein by reference herein.

### BACKGROUND

### 1. Field

Aspects of some embodiments of the present disclosure relate to a display device, a method of manufacturing the display device, and an electronic device including the display device.

### 2. Description of the Related Art

Display devices display a screen and include liquid crystal displays (LCDs), organic light-emitting diodes (OLEDs), etc. The display devices are used in various electronic devices such as mobile phones, navigation devices, digital cameras, electronic books, portable game consoles, various terminals, etc.

Organic light-emitting display (OLED) devices use an active matrix scheme using thin-film transistors and connect the thin-film transistors to pixel electrodes, and are driven according to a voltage maintained by a capacitor capacity of the thin-film transistors. In OLED devices, a plurality of holes are used in a portion where connections are required between wires and electrodes, and between electrodes, and an aperture ratio is reduced due to the plurality of holes.

The above information disclosed in this Background section is only for enhancement of understanding of the background and therefore the information discussed in this Background section does not necessarily constitute prior art.

### SUMMARY

Aspects of some embodiments of the present disclosure relate to a display device, a method of manufacturing the display device, and an electronic device including the display device, and for example, to a display device having relatively improved reliability, a method of manufacturing the display device, and an electronic device including the display device.

Aspects of some embodiments according to the present disclosure include a display device and an electronic device capable of improving an aperture ratio of a pixel.

However, such characteristics are just examples, and the scope of embodiments according to the present disclosure are not limited thereto.

According to some embodiments of the present disclosure, a display device includes a substrate including a display area, a thin-film transistor arranged on the display area, a first insulating layer arranged on the thin-film transistor and including a through hole exposing a source electrode or a drain electrode of the thin-film transistor, a second insulating layer arranged on the first insulating layer and including a first via hole and a second via hole which are spaced apart from each other, and a pixel electrode arranged on the second insulating layer and electrically connected to the thin-film transistor via the through hole, in which the first via hole overlaps the through hole, and the second via hole does not overlap the through hole.

According to some embodiments of the present disclosure, the display device may further include an initialization voltage line extending in a first direction on the substrate, in which the second via hole overlaps the initialization voltage line.

According to some embodiments of the present disclosure, the second via hole may not overlap the pixel electrode.

According to some embodiments of the present disclosure, the second via hole may not overlap the source electrode or the drain electrode exposed by the through hole.

According to some embodiments of the present disclosure, a width of the second via hole may be less than or equal to a width of the first via hole.

According to some embodiments of the present disclosure, a width of the first via hole may be less than or equal to a width of the through hole.

According to some embodiments of the present disclosure, a width of the first via hole may be at most twice a width of the through hole.

According to some embodiments of the present disclosure, the source electrode or the drain electrode of the thin-film transistor may include copper (Cu).

According to some embodiments of the present disclosure, the second via hole may expose a portion of the first insulating layer.

According to some embodiments of the present disclosure, the second via hole may be formed as plurality.

According to some embodiments of the present disclosure, a method of manufacturing a display device includes forming, on a display area of a substrate, a thin-film transistor including a source electrode and a drain electrode, forming, on the thin-film transistor, a first insulating layer including a through hole exposing the source electrode or the drain electrode, forming, on the first insulating layer, a second insulating layer including a first via hole and a second via hole, and forming, on the second insulating layer, a pixel electrode electrically connected to the source electrode or the drain electrode via the through hole, in which the first via hole overlaps the through hole, and the second via hole does not overlap the through hole.

According to some embodiments of the present disclosure, the method may further include forming an initialization voltage line extending in a first direction on the substrate, in which the second via hole overlaps the initialization voltage line.

According to some embodiments of the present disclosure, the second via hole may not overlap the pixel electrode.

According to some embodiments of the present disclosure, a width of the second via hole may be less than or equal to a width of the first via hole.

According to some embodiments of the present disclosure, a width of the first via hole may be less than or equal to a width of the through hole.

According to some embodiments of the present disclosure, a width of the first via hole may be at most twice a width of the through hole.

According to some embodiments of the present disclosure, the source electrode or the drain electrode of the thin-film transistor may include copper (Cu).

According to some embodiments of the present disclosure, the second via hole may expose a portion of the first insulating layer.

According to some embodiments of the present disclosure, the second via hole may be formed as plurality.

According to some embodiments of the present disclosure, an electronic device includes a processor configured to generate a scan input signal, a power module configured to generate a scan input voltage, and a display device configured to receive the scan input signal and the scan input voltage and output a scan signal to a pixel circuit, in which the display device includes a substrate including a display area, a thin-film transistor arranged on the display area, a first insulating layer arranged on the thin-film transistor and including a through hole exposing a source electrode or a drain electrode of the thin-film transistor, a second insulating layer arranged on the first insulating layer and including a first via hole and a second via hole which are spaced apart from each other, and a pixel electrode arranged on the second insulating layer and electrically connected to the thin-film transistor via the through hole, and in which the first via hole overlaps the through hole, and the second via hole does not overlap the through hole.

Other aspects, features, and characteristics other than those described above will become apparent from the following figures, claims, and the detailed description of the disclosure.

### BRIEF DESCRIPTION OF THE DRAWINGS

The above and other aspects, features, and characteristics of certain embodiments of the present disclosure will be more apparent from the following description taken in conjunction with the accompanying drawings in which:

FIG. 1 is a schematic plan view of a display device according to some embodiments of the present disclosure;

FIG. 2 is a schematic diagram showing wires included in a display device according to some embodiments of the present disclosure;

FIG. 3 is an equivalent circuit diagram of a pixel according to some embodiments of the present disclosure;

FIG. 4 is a layout diagram showing a part of a region including a pixel unit in a display region of the display device of FIG. 1;

FIG. 5 is a cross-sectional view schematically showing a cross-section of the display device shown in FIG. 4;

FIG. 6 is an enlarged plan view of a portion A of FIG. 4;

FIGS. 7 to 9 are layout diagrams schematically showing, layer by layer, components including thin-film transistors, a storage capacitor, etc., of the display device shown in FIG. 4;

FIG. 10 is a block diagram of an electronic device according to some embodiments of the present disclosure; and

FIG. 11 is a block diagram of an electronic device according to various embodiments of the present disclosure.

### DETAILED DESCRIPTION

Embodiments according to the present disclosure may have various modifications thereto and various embodiments, and thus particular embodiments will be illustrated in the drawings and described in detail in a detailed description. Effects and features of the present disclosure, and methods for achieving them will become clear with reference to the embodiments described later in detail together with the drawings. However, embodiments according to the present disclosure are not limited to the embodiments disclosed below and may be implemented in various forms.

In the following embodiments, the terms such as first, second, etc., have been used to distinguish one component from other components, rather than limiting.

In the following embodiments, singular forms include plural forms unless apparently indicated otherwise contextually.

In the following embodiments, the terms “include”, “have”, or the like, are intended to mean that there are features, or components, described herein, but do not preclude the possibility of adding one or more other features or components.

In the following embodiments, when a portion, such as a film, a region, a component, etc., is present on or above another portion, this case may include not only a case where it is directly on another portion, but also a case where another film, region, component, etc., is arranged between the portion and the other portion.

In the drawings, the size of components may be exaggerated or reduced for convenience of description. For example, as the size and thickness of each component shown in the drawings are arbitrarily shown for convenience of description, embodiments according to the present disclosure are not necessarily limited to the illustration.

When a certain embodiment may be implemented otherwise, a particular process order may be performed differently from the order described. For example, two processes described in succession may be performed simultaneously (or substantially simultaneously), or may be performed in an order reverse to the order described.

Hereinafter, aspects of some embodiments of the present disclosure will be described in more detail with reference to the accompanying drawings, and in description with reference to the drawings, the same or corresponding components are given the same reference numerals, and some redundant description thereof may be omitted.

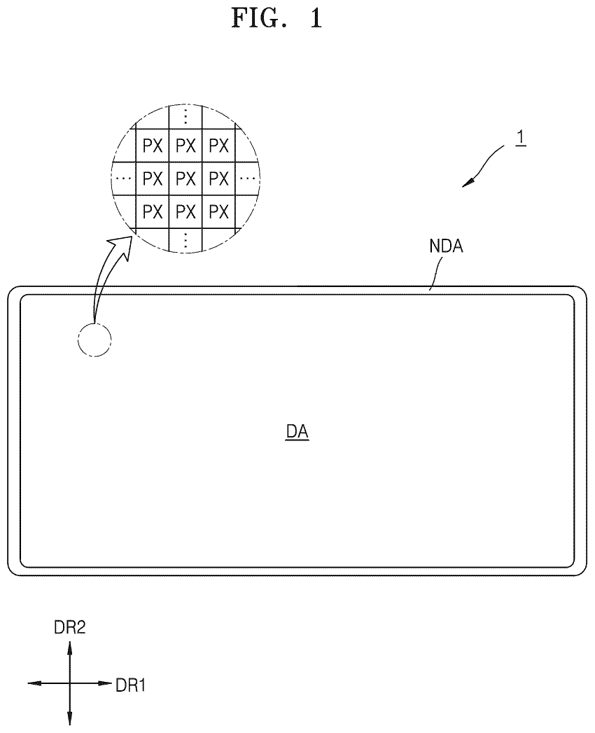

FIG. 1 is a schematic plan view of a display device 1 according to some embodiments of the present disclosure.

Referring to FIG. 1, the display device 1 may be applicable to various electronic devices including small to medium electronic devices such as tablet personal computers (PCs), smart phones, car navigation units, cameras, center information displays (CIDs) provided in cars, wristwatch-type electronic devices, personal digital assistants (PDAs), portable multimedia players (PMPs), and game consoles, medium to large electronic such as televisions, outdoor billboards, monitors, PCs, and laptop computers, and so forth. However, these are presented as embodiments, and it would be obvious that the present disclosure may be employed in other electronic devices without departing from the concept of the present disclosure.

The display device 1 may include a display panel providing a display screen. Examples of the display panel may include inorganic light-emitting diode display panels, organic light-emitting display panels, quantum dot light-emitting display panels, plasma display panels, field emission display panels, etc. Hereinbelow, an organic light-emitting diode is used as an example of a display panel, but embodiments according to the present disclosure are not limited thereto, and other display panels may be used as long as the same technical idea is applicable thereto.

The shape of the display device 1 may be modified in various ways. According to some embodiments, the display device 1 may have a shape such as a long-width rectangle, a long-length rectangle, a square, a rectangle with rounded corners (vertices), other polygons, a circle, etc. The shape of a display area DA of the display device 1 may also be similar to the overall shape of the display device 1. In FIG. 1, the display device 1 and the display area DA having a shape of the long-width rectangle are shown.

The display device 1 may include two first sides extending in a direction and two second sides extending in another direction crossing the direction. A corner where the first side and the second side of the display device 1 meet each other may have a right angle, but embodiments according to the present disclosure are not limited thereto, and may also form a curved surface. According to some embodiments, the first side may be shorter than the second side, but embodiments according to the present disclosure are not limited thereto. A planar shape of the display device 1 may not be limited to the illustration, and may be applied in circular or other shapes.

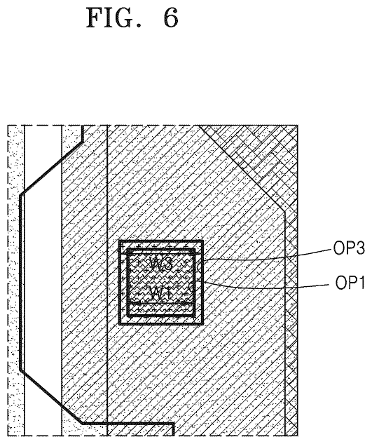

The display device 1 may include the display area DA and a non-display area NDA. The display area DA may be an area where a screen or images may be displayed, and the non-display area NDA may be an area where a screen or images are not displayed. The display area DA may also be referred to as an active area, and the non-display area NDA may also be referred to as an inactive area. This may be understood as meaning that a substrate SUB (see FIG. 6) included in the display device 1 includes the display area DA and a non-display area NDA. The display area DA may generally occupy the center of the display device 1. The non-display area NDA may surround (e.g., in a periphery or outside a footprint of) the display area DA.

The display area DA may include a plurality of pixels PX. The plurality of pixels PX may be arranged in a matrix direction. The shape of each pixel PX may be a rectangle or a square on a plane, but embodiments according to the present disclosure are not limited thereto, and may also be a rhombic shape with each side tilted in a direction. Each pixel PX may be arranged alternately in a stripe type or a pentile type.

Each pixel PX may represent a sub-pixel and may include a light-emitting element and a pixel circuit connected thereto. Each of the pixels PX may include one or more light-emitting elements that emit light of a specific wavelength to display a specific color. The display device 1 may display images using light emitted from the pixels PX.

The non-display area NDA may be arranged around (e.g., in a periphery or outside a footprint of) the display area DA. The non-display area NDA may surround (e.g., in a periphery or outside a footprint of) the display area DA entirely or partially. The display area DA may have a rectangular shape, and the non-display area NDA may be arranged adjacent to four sides of the display area DA. The non-display area NDA may form a bezel of the display device 1. In each non-display area NDA, wires or circuit driving units included in the display device 1 may be placed, or external devices may be mounted.

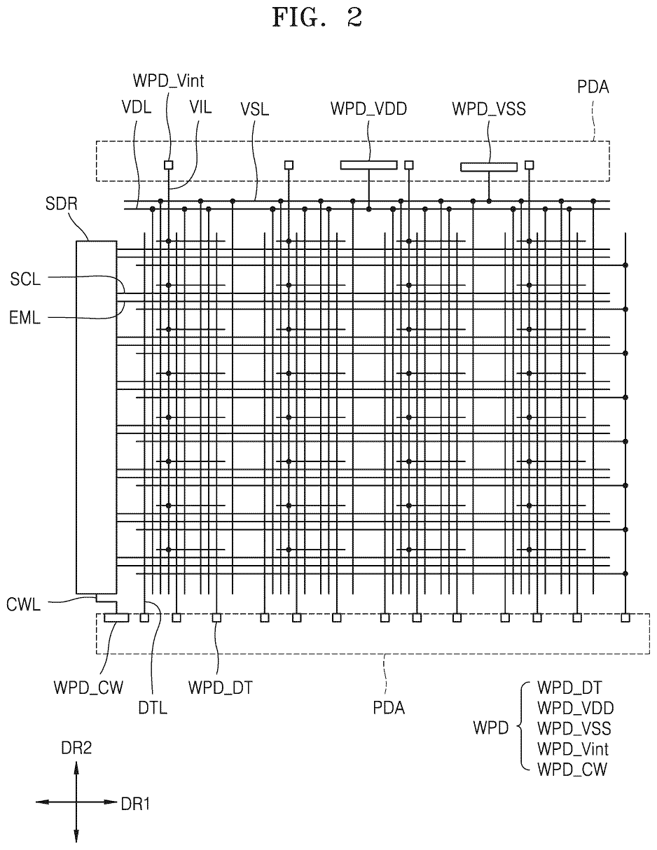

FIG. 2 is a schematic diagram showing wires included in the display device 1 according to some embodiments of the present disclosure.

Referring to FIG. 2, the display device 1 may include a plurality of wires. The plurality of wires may include a scan line SCL, a sensing line SSL, a data line DTL, an initialization voltage line VIL, a first voltage line VDL, a second voltage line VSL, etc. According to some embodiments, the display device 1 may further include other wires. FIG. 2 merely shows a schematic arrangement of the plurality of wires.

The scan line SCL and the sensing line SSL may extend in a first direction DR1. The scan line SCL and the sensing line SSL may be connected to a scan driving unit SDR. The scan driving unit SDR may include a driving circuit. The scan driving unit SDR may be arranged at one side of the first direction DR1 of the display area DA, but embodiments according to the present disclosure are not limited thereto. The scan driving unit SDR may be connected to a signal connection line CWL, and at least one end of the signal connection line CWL may form a pad WPD_CW on the non-display area NDA so as to be connected to an external device.

Herein, ‘connection’ may mean not only that one member is connected to another member through mutual physical contact, but also that one member is connected through another member. It may also be understood as an integrated single member with any one portion and another portion being connected to each other due to the integrated member. Connection between any one member and another member may be interpreted to include not only a direct contact connection but also an electrical connection through the other member.

The data line DTL and the initialization voltage line VIL may extend in a second direction DR2 crossing the first direction DR1. The initialization voltage line VIL may include a portion extending in the second direction DR2 and a portion extending from the portion in the first direction DR1. The first voltage line VDL and the second voltage line VSL may also include a portion extending in the second direction DR2 and a portion connected thereto and extending in the first direction DR1. The first voltage line VDL and the second voltage line VSL may have a mesh structure, but embodiments according to the present disclosure are not limited thereto.

The data line DTL, the initialization voltage line VIL, the first voltage line VDL and the second voltage line VSL may be electrically connected to at least one wire pad WPD. Each wiring pad WPD may be arranged in the non-display area NDA. According to some embodiments, a wire pad WPD_DT (hereinafter, referred to as a ‘data pad’) of the data line DTL may be arranged in a pad area PDA at one side of the second direction DR2 of the display area DA, and a wire pad WPD_Vint (hereinafter, referred to as an ‘initialization voltage pad’) of the initialization voltage line VIL, a wire pad WPD_VDD (hereinafter, referred to as a ‘first power pad’) of the first voltage line VDL, and a wire pad WPD_VSS (hereinafter, referred to as a ‘second power pad’) of the second voltage line VSL may be arranged in the pad area PDA located at another side of the second direction DR2 of the display area DA. As another example, the data pad WPD_DT, the initialization voltage pad WPD_Vint, the first power pad WPD_VDD, and the second power pad WPD_VSS may all be arranged in the same area, for example, the non-display area NDA located above the display area DA. An external device may be mounted on the wire pad WPD. The external device may be mounted on the wire pad WPD via an anisotropic conductive film, ultrasonic bonding, etc.

Each pixel PX of the display device 1 may include a pixel driving circuit. The above-described wires may apply a driving signal to each pixel driving circuit while passing through each pixel PX or a periphery thereof. The pixel driving circuit may include a transistor and a capacitor. The number of transistors and capacitors in each pixel driving circuit may be changed variously. According to some embodiments, each pixel PX of the display device 1 may have a 4T1C structure in which the pixel driving circuit includes four transistors and one capacitor. While the pixel driving circuit is described using the 4T1C structure as an example, embodiments according to the present disclosure are not limited thereto and various other modified pixel PX structures such as a 2T1C structure, a 3T1C structure, a 7T1C structure, etc., may be applied.

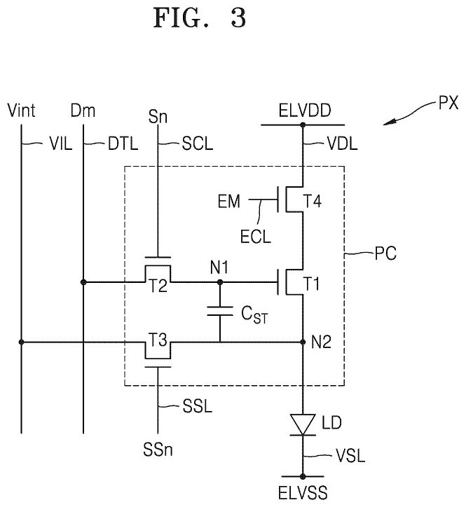

FIG. 3 is an equivalent circuit diagram of a pixel according to some embodiments. Although FIG. 3 illustrates various components in a circuit of a pixel according to some embodiments, embodiments according to the present disclosure are not limited thereto, and according to some embodiments, the pixel circuit may include additional components or fewer components, without departing from the spirit and scope of embodiments according to the present disclosure.

Referring to FIG. 3, one pixel PX of the display device 1 according to some embodiments may include a pixel driving circuit PC connected to the scan line SL and the data line DL and a light-emitting diode LD connected to the pixel driving circuit PC.

The pixel driving circuit PC may include four thin-film transistors T1, T2, T3, and T4 and one storage capacitor Cst. The thin-film transistors T1, T2, T3, and T4 and the storage capacitor Cst may be connected to the signal lines SCL, ECL, and DTL, the initialization voltage line VIL, the first voltage line VDL, and the second voltage line VSL.

The light-emitting diode LD may emit light depending on current supplied through a first transistor T1. The light-emitting diode LD may include a pixel electrode, a counter electrode, and at least one light-emitting element arranged therebetween. The light-emitting element may emit light of a specific wavelength range by an electric signal transmitted from the pixel electrode and the counter electrode. The pixel electrode of the light-emitting diode LD may be connected to a source electrode of the first transistor T1, and the counter electrode may be connected to the second voltage line VSL supplied with a low-potential voltage (hereinafter, a second power voltage) lower than a high-potential voltage (hereinafter, a first power voltage) of the first voltage line VDL.

Signal lines may include the scan line SCL that transmits a scan signal Sn, an operation control line ECL that transmits an operation control signal EM, and a data line DTL that transmits a data signal Dm. The initialization voltage line VIL may transmit an initialization voltage Vint that initializes the pixel electrode of the light-emitting diode LD, and the first voltage line VDL may transmit a first power voltage EVLDD, which is a driving voltage of the driving transistor T1.

The first transistor T1 may control the current flowing from the first voltage line VDL to which the first power voltage EVLDD is supplied to the light-emitting diode LD, based on the voltage difference between a gate electrode and a source electrode thereof. For example, the first transistor T1 may be a driving transistor for driving the light-emitting diode LD. The gate electrode of the first transistor T1 may be connected to the source electrode of the second transistor T2 via a first node N1, the source electrode may be connected to the pixel electrode of the light-emitting diode LD, and the drain electrode may be connected to the first voltage line VDL to which a first power voltage ELVDD is applied via the fourth transistor T4.

The second transistor T2 may be turned on by the scan signal Sn of the scan line SCL to connect the data line DTL to the gate electrode of the first transistor T1. A gate electrode of the second transistor T2 may be connected to the scan line SCL, the source electrode may be connected to the gate electrode of the first transistor T1, and the drain electrode may be connected to the data line DTL.

The third transistor T3 may be turned on by a sensing signal SSn of the sensing line SSL to connect the initialization voltage line VIL to the pixel electrode of the light-emitting diode LD. A gate electrode of the third transistor T3 may be connected to the sensing line SSL, the drain electrode may be connected to the initialization voltage line VIL, and the source electrode may be connected to the pixel electrode of the light-emitting diode LD or the source electrode of the first transistor T1 through a second node N2.

The fourth transistor T4 may be turned on by the operation control signal EM of the operation control line ECL to transmit a first power voltage ELVDD (a driving voltage) to the light-emitting diode LD such that driving current may flow to the light-emitting diode LD. A gate electrode of the fourth transistor T4 may be connected to the operation control line ECL, the drain electrode may be connected to the first voltage line VDL, and the source electrode may be connected to the drain electrode of the first transistor T1.

According to some embodiments, the source electrode and drain electrode of each transistor T1, T2, T3, or T4 are not limited to the foregoing description and vice versa.

The storage capacitor Cst may be formed between the gate electrode and the source electrode of the first transistor T1. The storage capacitor Cst may include a first capacitor electrode CE1 and a second capacitor electrode CE2. The first capacitor electrode CE1 may be connected to the source region of the first transistor T1 through the second node N2, and the second capacitor electrode CE2 may be connected to the gate electrode of the first transistor T1 through the first node N1. The storage capacitor Cst may store a differential voltage between a gate voltage and a source voltage of the first transistor T1.

Each of the transistors T1, T2, T3, and T4 may include a thin-film transistor. In FIG. 3, the description is mainly made of the fact that each transistor T1, T2, T3, or T4 includes an N-type metal oxide semiconductor field-effect transistor (MOSFET), but embodiments according to the present disclosure are not limited thereto. That is, each of the transistors T1, T2, and T3 may be formed as a P-type MOSFET, or some thereof may be formed as N-type MOSFETs and other some as P-type MOSFETs.

Hereinafter, the structure of one pixel PX of the display device 1 according to some embodiments will be described in detail with further reference to other drawings.

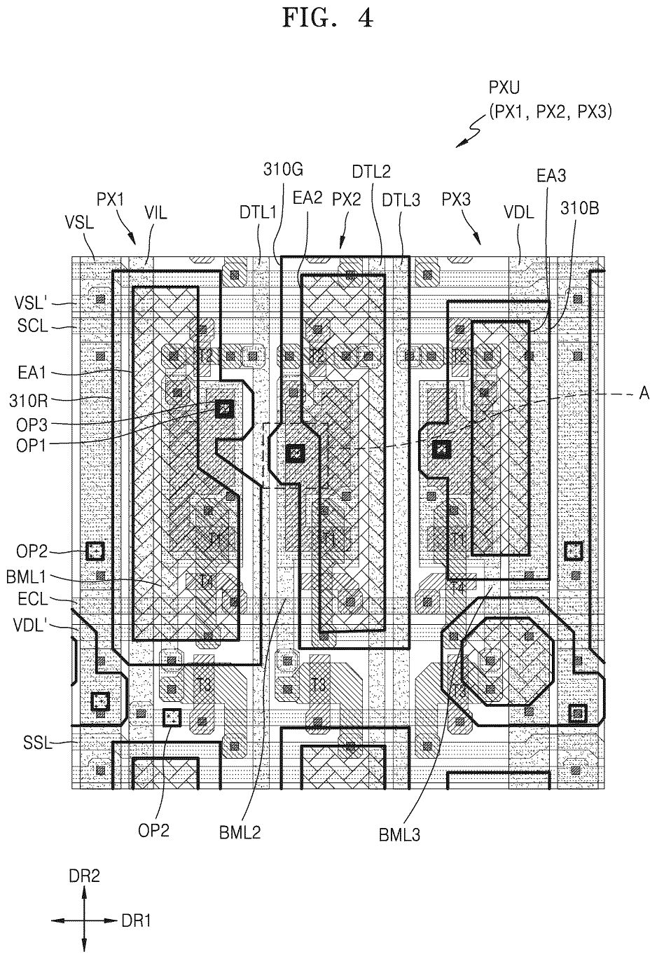

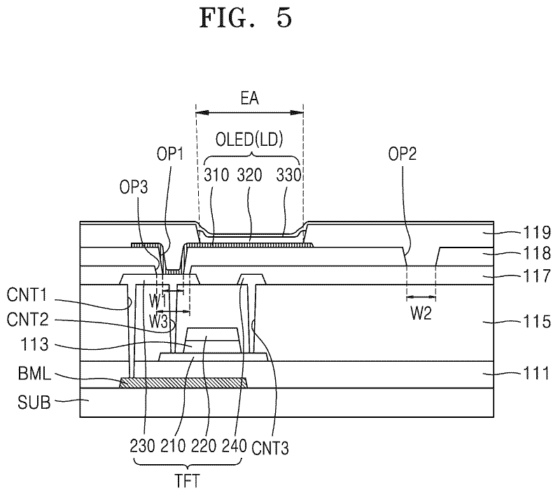

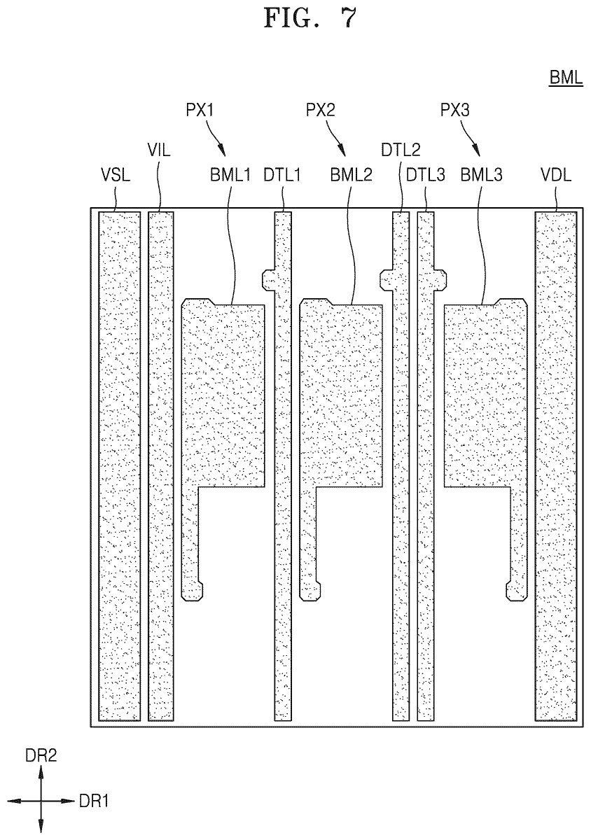

FIG. 4 is a layout diagram showing a part of a region including a pixel unit PXU in a display region of the display device of FIG. 1, FIG. 5 is a cross-sectional view schematically showing a cross-section of the display device shown in FIG. 4, and FIG. 6 is an enlarged plan view of a portion A of FIG. 4. FIGS. 7 to 9 are layout diagrams schematically showing, layer by layer, components including thin-film transistors, a storage capacitor, etc., of the display device shown in FIG. 4.

In each of the drawings below, opposite sides of the first direction DR1 may be respectively referred to as left and right sides, and opposite sides of the second direction DR2 may be respectively referred to as upper and lower sides.

Referring to FIG. 4, the pixel unit PXU may include at least one pixel PX. According to some embodiments, the pixel unit PXU may include three pixels PX1, PX2, and PX3, but the number of pixels PX included in the pixel unit PXU is not limited thereto, and the pixel unit PXU may include a smaller or larger number of pixels.

A plurality of pixels PXn (n is an integer from 1 to 3) included in the pixel unit PXU may emit light of different colors. According to some embodiments, a first pixel PX1 may emit red light, a second pixel PX2 may emit green light, and a third pixel PX3 may emit blue light. However, embodiments according to the present disclosure are not limited thereto, and each pixel PX1, PX2, or PX3 may emit light of the same color.

Although the plurality of pixels PX included in the pixel unit PXU are arranged in a stripe shape or arrangement, they may be arranged in a pentile shape according to some embodiments. For convenience of a description, FIG. 4 also shows parts of other pixels located under a first pixel PX1, a second pixel PX2, and a third pixel PX3. A structure as shown in FIG. 4 may be repeatedly arranged in the first direction DR1 and/or the second direction DR2. Between the pixels PX, there may be an area that does not belong to any pixel PX. According to some embodiments, the initialization voltage line VIL, the first voltage line VDL, or the second voltage line VSL may exist between adjacent pixels PX.

As described above, each pixel PX1, PX2, or PX3 included in the pixel unit PXU may include a plurality of transistors T1 to T4 and a storage capacitor Cst as pixel circuit elements, and may be connected to the scan line SCL, the data line DTL, the operation control line ECL, the sensing line SSL, the first voltage line VDL, the second voltage line VSL, and the initialization voltage line VIL.

The scan line SCL may extend in the first direction DR1 and may be arranged across the plurality of pixels PX arranged in the first direction DR1. The plurality of scan lines SCL may be spaced apart from each other in the second direction DR2 across the entire display area DA. According to some embodiments, the scan line SCL may be positioned on an upper side with respect to the center of each pixel PX. The scan line SCL may be electrically connected to the gate electrode of the second transistor T2 and may apply a scan signal to the second transistor T2.

The sensing line SSL may extend in the first direction DR1 and may be arranged across the plurality of pixels PX arranged in the first direction DR1. The plurality of sensing lines SSL may be spaced apart from each other in the second direction DR2 across the entire display area DA. According to some embodiments, the sensing line SSL may be positioned on a lower side with respect to the center of each pixel PX. The sensing line SSL may be electrically connected to the gate electrode of the third transistor T3 and may apply a scan signal to the third transistor T3.

The scan line SCL and the sensing line SSL may include a third conductive layer described below.

The data line DTL may extend in the second direction DR2 and may be arranged across the plurality of pixels PX arranged in the second direction DR2. The plurality of data lines DTL may be spaced apart from each other in the first direction DR1 across the entire display area DA. According to some embodiments, the data line DTL may be positioned on a right side or a left side of each pixel PX. The data line DTL may be electrically connected to a source electrode or a drain electrode of the second transistor T2 and may apply a data signal to the second transistor T2.

The initialization voltage line VIL may extend in the second direction DR2 and may be arranged across the plurality of pixels PX arranged in the second direction DR2. The plurality of initialization voltage lines VIL may be spaced apart from each other in the first direction DR1 across the entire display area DA.

According to some embodiments, the initialization voltage line VIL may be arranged for every three pixels PX or each pixel unit PXU. According to some embodiments, the initialization voltage line VIL may be arranged on a left side with respect to the center of each pixel unit PXU and may be arranged on a left side of a lower capacitor electrode BML1 included in any one pixel (e.g., the first pixel PX1). The initialization voltage line VIL may be electrically connected to a source electrode or a drain electrode of the third transistor T3 and may apply an initialization voltage to the third transistor T3.

The data line DTL and the initialization voltage line VIL may include a first conductive layer described below.

The first voltage line VDL and the second voltage line VSL may extend in the second direction DR2 and may be arranged across the plurality of pixels PX adjacent to each other in the second direction DR2. A plurality of first voltage lines VDL or a plurality of second voltage lines VSL may be spaced apart from each other in the first direction DR1 across the entire display area DA. According to some embodiments, the first voltage line VDL may be arranged on the right side with respect to the center of each pixel unit PXU, and the second voltage line VSL may be arranged on the left side with respect to the center of each pixel unit PXU.

The first voltage line VDL may be electrically connected to either a source electrode or a drain electrode of the fourth transistor T4, and the first power voltage ELVDD may be applied to the first transistor T1 via the fourth transistor T4. The second voltage line VSL may be electrically connected to a counter electrode of the light-emitting diode LD to apply a second power voltage ELVSS to the light-emitting diode LD. The first voltage line VDL and the second voltage line VSL may include the first conductive layer.

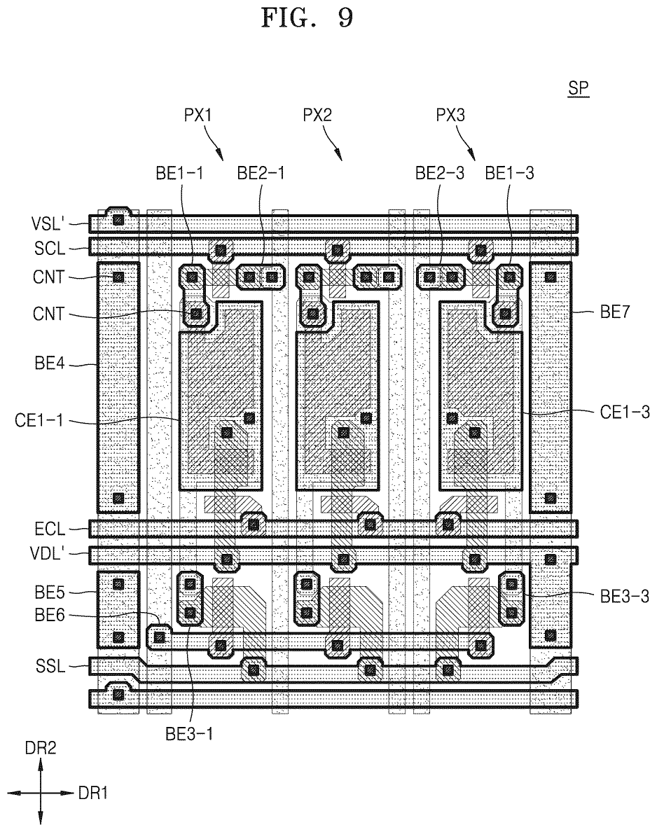

The first voltage line VDL may be electrically connected to a first upper voltage line VDL′ extending in the first direction DR1 via a contact hole. The second voltage line VSL may be electrically connected to a second upper voltage line VSL′ extending in the first direction DR1 via the contact hole. The first upper voltage line VDL′ and the second upper voltage line VSL′ may include the third conductive layer, as shown in FIG. 9.

A layout diagram along with a cross-sectional structure of each pixel PX will be described in detail. For convenience of a description, some components will be described based on the first pixel PX1, but these components may also be arranged in the second pixel PX2 and the third pixel PX3.

The display device 1 may include a substrate SUB, and pixel circuit elements may be arranged on the substrate SUB. The substrate SUB may include an insulating material such as glass, quartz, polymer resin, etc. The substrate SUB may be a rigid substrate, but may also be a flexible substrate capable of bending, folding, rolling, etc.

On the substrate 100, a lower metal layer BML may be arranged. The lower metal layer BML may include the first voltage line VDL, the second voltage line VSL, the initialization voltage line VIL, a first lower capacitor electrode BML1, and a first data line DTL1. Among them, the first voltage line VDL, the second voltage line VSL, the initialization voltage line VIL, and the first data line DTL1 may extend in the second direction DR2.

The lower capacitor electrode BML1 may have an isolated shape in each pixel PX. The lower capacitor electrode BML1 may be electrically connected to a first capacitor electrode CE1-1 located thereon via the contact hole. The lower capacitor electrode BML1 may be arranged to overlap an active layer of the first transistor T1. The lower capacitor electrode BML1 may prevent or reduce light entering the first transistor T1 by including a light-blocking material.

The lower metal layer BML may be the first conductive layer including a first conductive material. The first conductive material may include a metal, an alloy, a conductive metal oxide, etc. According to some embodiments, the lower metal layer BML may include silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), etc. The lower metal layer BML may have a multilayer structure. According to some embodiments, the lower metal layer BML may have a two-layer structure including an aluminum layer having a thickness of 3500 Å and a titanium layer having a thickness of 300 Å.

As described above, the lower metal layer BML, i.e., the first conductive layer, may be applied as a signal wire of the pixel PX, such as the first voltage line VDL, the second voltage line VSL, the initialization voltage line VIL, and the data line DTL. The lower metal layer BML may include a low-resistance material to lower the resistance of the signal wire, and may be formed to have a selected thickness.

A buffer layer 111 may cover the lower metal layer BML and may be arranged over the entire surface of the substrate SUB. The buffer layer 111 may be formed on the substrate SUB to protect the thin-film transistors of the pixel PX from moisture or impurities penetrating through the substrate SUB which is vulnerable to moisture permeation, and may perform a surface planarization function.

The buffer layer 111 may include an insulating material. The buffer layer 111 may include a plurality of inorganic layers alternately stacked. According to some embodiments, the buffer layer 111 may be formed as a multilayer in which one or more inorganic layers of a silicon oxide layer (SiOx), a silicon nitride layer (SiNx), and a silicon oxynitride (SiON) are alternately stacked.

The semiconductor layer 210 may be arranged on the buffer layer 111. The semiconductor layer 210 may include an active layer of each transistor T1, T2, T3, or T4.

According to some embodiments, the semiconductor layer 210 may include polycrystalline silicon, monocrystal silicon, oxide semiconductor, etc. Polycrystalline silicon may be formed by crystallizing amorphous silicon. The oxide semiconductor may be an oxide semiconductor containing indium (In). According to some embodiments, the oxide semiconductor may include indium-tin oxide (ITO), indium-zinc oxide (IZO), indium-gallium oxide (IGO), indium-zinc-tin oxide (IZTO), indium-gallium-zinc oxide (IGZO), indium-gallium-tin oxide (IGTO), indium-gallium-zinc-tin oxide (IGZTO), or the like.

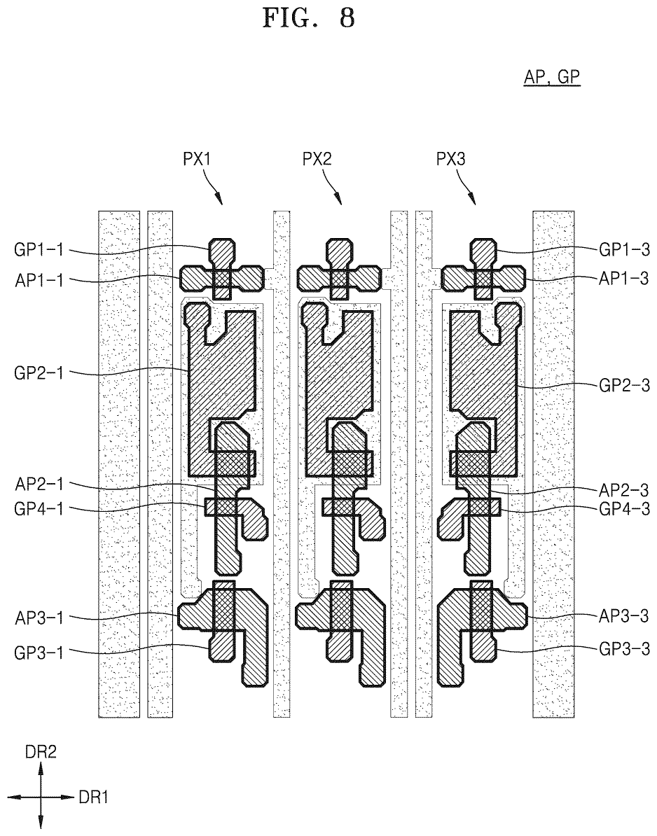

The semiconductor layer 210 may include a plurality of semiconductor patterns AP spaced apart from each other. According to some embodiments, the semiconductor layer 210 may include a first semiconductor pattern AP1-1, a second semiconductor pattern AP2-1, and a third semiconductor pattern AP3-1 that are spaced apart from each other, as shown in FIG. 8. The first transistor T1, the second transistor T2, the third transistor T3, and the fourth transistor T4 may be arranged along the semiconductor pattern AP of the semiconductor layer 210.

The first semiconductor pattern AP1-1 may be electrically connected to the data line DTL. A source region, an active region, and a drain region of the second transistor T2 may be arranged on the first semiconductor pattern AP1-1. The first semiconductor pattern AP1-1 may be referred to as a switching semiconductor layer.

The second semiconductor pattern AP2-1 may be electrically connected to the first voltage line VDL. The source region, the active region, and the drain region of the first transistor T1 and the source region, the active region, and the drain region of the fourth transistor T4 may be arranged on the second semiconductor pattern AP2-1. The second semiconductor pattern AP2-1 may be referred to as a driving semiconductor layer or an operation control semiconductor layer.

The sensing line SSL may be electrically connected to the third semiconductor pattern AP3-1. The source region, the active region, and the drain region of the third transistor T3 may be arranged on the third semiconductor pattern AP3-1. The third semiconductor pattern AP3-1 may be referred to as a sensing semiconductor layer.

The semiconductor pattern AP of each pixel PX1, PX2, or PX3 included in the pixel unit PXU may be formed identically or symmetrically. According to some embodiments, semiconductor patterns AP1-1, AP2-1, and AP3-1 of the first pixel PX1 and semiconductor patterns AP3-1, AP2-3, and AP3-3 of the third pixel PX3 may be arranged symmetrically with respect to a virtual line.

A gate insulating layer 113 may be placed on the semiconductor layer 210. The gate insulating layer 113 may include an insulating material. According to some embodiments, the gate insulating layer 113 may include an inorganic insulating layer such as silicon oxide, silicon nitride, silicon oxynitride, aluminum oxide, etc. According to some embodiments, the gate insulating layer 113 may be patterned into a shape corresponding to a gate electrode 220, but embodiments according to the present disclosure are not limited thereto, and the gate insulating layer 113 may be formed to cover both the buffer layer 111 and the semiconductor layer 210.

The gate electrode 220 may be arranged on the gate insulating layer 113. The gate electrode 220 may include a second conductive layer including a second conductive material. The gate electrode 220 may include a plurality of gate electrode patterns GP spaced apart from each other. As shown in FIG. 8, according to some embodiments, the gate electrode 220 may include a first gate electrode pattern GP1-1, a second gate electrode pattern GP2-1, a third gate electrode pattern GP3-1, and a fourth gate electrode pattern GP4-1 that are spaced apart from each other. In FIG. 8, for convenience, a gate electrode pattern GP is shown together with the lower metal layer BML and the semiconductor pattern AP.

The first gate electrode pattern GP1-1 may have an isolated shape, and a part of the first gate electrode pattern GP1-1 may overlap the first semiconductor pattern AP1-1 located under the first gate electrode pattern GP1-1. The overlapping part of the first gate electrode pattern GP1-1, i.e., a part overlapping the active region of the semiconductor layer 210, may function as the gate electrode of the second transistor T2.

The second gate electrode pattern GP2-1 may have an isolated shape, and a part of the second gate electrode pattern GP2-1 may overlap the second semiconductor pattern AP2-1 located under the second gate electrode pattern GP2-1. A part of the second gate electrode pattern GP2-1, which overlaps the second semiconductor pattern AP2-1, may function as a gate electrode of the first transistor T1. The second gate electrode pattern GP2-1 may overlap a first capacitor electrode CE1-1 described later to function as a second capacitor electrode CE2 of the storage capacitor Cst.

The second semiconductor pattern AP2-1 may overlap a part of the fourth gate electrode pattern GP4-1 as well as the second gate electrode pattern GP2-1. The fourth gate electrode pattern GP4-1 may have an isolated shape, and a part of the fourth gate electrode pattern GP4-1, which overlaps the second semiconductor pattern AP2-1, may function as the gate electrode of the fourth transistor T4.

The third gate electrode pattern GP3-1 may have an isolated shape, and a part of the third gate electrode pattern GP3-1 may overlap the third semiconductor pattern AP3-1 located under the third gate electrode pattern GP3-1. A part of the third gate electrode pattern GP3-1, which overlaps the third semiconductor pattern AP3-1, may function as the gate electrode of the third transistor T3.

The gate electrode pattern GP of each pixel PX1, PX2, or PX3 included in the pixel unit PXU may be formed identically or symmetrically. According to some embodiments, the gate electrode patterns GP1-1, GP2-1, GP3-1, and GP4-1 of the first pixel PX1 and the gate electrode patterns GP1-3, GP2-3, GP3-3, and GP4-3 of the third pixel PX3 may be arranged symmetrically with respect to a virtual line.

The gate electrode pattern GP may include a second conductive layer including a second conductive material. The second conductive material may include a metal, an alloy, a conductive metal oxide, a transparent conductive material, etc. According to some embodiments, the gate electrode pattern GP may include Ag, an alloy containing Ag, Mo, an alloy containing Mo, Al, an alloy containing Al, AlN, W, WN, Cu, Ni, Cr, CrN, Ti, Ta, Pt, Sc, ITO, IZO, etc. The gate electrode pattern GP may have a multi-layer structure, for example, the gate electrode pattern GP may have a two-layer structure including a titanium layer having a thickness of 300 Å and a molybdenum layer having a thickness of 2500 Å.

An interlayer insulating layer 115 may be arranged on the buffer layer 111, covering the gate electrode 220. The interlayer insulating layer 115 may include an inorganic insulating material, an organic insulating material, or a combination thereof. Examples of the inorganic insulating material available as the interlayer insulating layer 115 may include silicon oxide, silicon nitride, silicon oxynitride, etc. Examples of the organic insulating material available as the interlayer insulating layer 115 may include polyimide, polyamide, acrylic resin, phenol resin, benzocyclobutene (BCB), etc. The interlayer insulating layer 115 may insulate a source electrode 230 and a drain electrode 240 from the gate electrode 220.

As shown in FIG. 5, a first contact hole CNT1, a second contact hole CNT2, and a third contact hole CNT3 may be respectively formed by etching a portion of the interlayer insulating layer 115 or the buffer layer 111. The first contact hole CNT1 may electrically connect the lower metal layer BML to a third conductive layer SP described later by passing through the interlayer insulating layer 115 and the buffer layer 111. The second contact hole CNT2 may expose a source region of the semiconductor layer 210, and the third contact hole CNT3 may expose a drain region of the semiconductor layer 210.

The third conductive layer SP may be located on the interlayer insulating layer 115. The third conductive layer SP may include the scan line SCL, the operation control line ECL, the first upper voltage line VDL′, the second upper voltage line VSL′, the sensing line SSL, the first capacitor electrode CE1-1, a first connection electrode BE1-1, a second connection electrode BE2-1, a third connection electrode BE3-1, a fourth connection electrode BE4, a fifth connection electrode BE5, a sixth connection electrode BE6, and a seventh connection electrode BE7. The third conductive layer SP may include the source electrode 230 and the drain electrode 240 of a thin-film transistor TFT.

The scan line SCL may partially overlap a first gate electrode pattern GP1-1 and may be electrically connected to the first gate electrode pattern GP1-1 via a contact hole. That is, the scan line SCL may be connected to the gate electrode of the second transistor T2.

The operation control line ECL may partially overlap a fourth gate electrode pattern GP4-1 and may be electrically connected to the fourth gate electrode pattern GP4-1 via a contact hole. That is, the operation control line ECL may be connected to the gate electrode of the fourth transistor T4.

The first upper voltage line VDL′ may partially overlap the first voltage line VDL and may be electrically connected to the first voltage line VDL via a contact hole. The first upper voltage line VDL′ may partially overlap the second semiconductor pattern AP2-1 and may be electrically connected to the fourth transistor T4 via a contact hole.

The second upper voltage line VSL′ may partially overlap the second voltage line VSL and may be electrically connected to the second voltage line VSL via a contact hole. The sensing line SSL may partially overlap the third semiconductor pattern AP3-1 and may be electrically connected to the third transistor T3 via a contact hole.

The first capacitor electrode CE1-1 may have an isolated shape and may be positioned on the lower capacitor electrode layer BML1 and the second gate electrode pattern GP2-1. The first capacitor electrode CE1-1 may form the storage capacitor Cst together with the second capacitor electrode CE2.

The first capacitor electrode CE1-1 may be electrically connected to the lower capacitor electrode BML1 positioned under the first capacitor electrode CE1-1 via a contact hole. In this case, the lower capacitor electrode BML1 may function as a capacitor electrode of the storage capacitor Cst together with the first capacitor electrode CE1-1. The first capacitor electrode CE1-1 may partially overlap the second semiconductor pattern AP2-1 positioned under the first capacitor electrode CE-1 and may be electrically connected to the first transistor T1 via a contact hole.

A first connection electrode BE1-1, a second connection electrode BE2-1, and a third connection electrode BE3-1 may be arranged in each of the first pixel PX1, the second pixel PX2, and the third pixel PX3. The first to third connection electrodes of each pixel may be formed identically or symmetrically. According to some embodiments, a first connection electrode BE1-1, a second connection electrode BE2-1, and a third connection electrode BE3-1 of the first pixel PX1 and a first connection electrode BE1-3, a second connection electrode BE2-3, and a third connection electrode BE3-3 of the third pixel PX3 may be arranged symmetrically with respect to a virtual line. The fourth connection electrode BE4, the fifth connection electrode BE5, the sixth connection electrode BE6, and the seventh connection electrode BE7 may be arranged in each pixel unit PXU.

One side of the first connection electrode BE1-1 may be connected to the first semiconductor pattern AP1-1 via a contact hole. Another side of the first connection electrode BE1-1 may be connected to the second gate electrode pattern GP2-1 via a contact hole. The first connection electrode BE1-1 may be understood as playing a role of a first node N1 (see FIG. 3) that electrically connects the first transistor T1 to the second transistor T2.

One side of the second connection electrode BE2-1 may be connected to a data line DTL1 via a contact hole, and another side of the second connection electrode BE2-1 may be connected to the first semiconductor pattern AP1-1 via a contact hole. The second connection electrode BE2-1 may electrically connect the data line DTL1 to the second transistor T2.

One side of the third connection electrode BE3-1 may be connected to a lower capacitor electrode BML1 via a contact hole, and another side of the third connection electrode BE3-1 may be connected to the third semiconductor pattern AP3-1 via a contact hole. The third connection electrode BE3-1 may be understood as playing a role of a second node N2 (see FIG. 3) that electrically connects the third transistor T3 to the storage capacitor Cst.

The fourth connection electrode BE4 and the fifth connection electrode BE5 may each have an isolated shape and may have a selected length in the second direction DR2. The fourth connection electrode BE4 and the fifth connection electrode BE5 may entirely or partially overlap the second voltage line VSL and may be electrically connected to the second voltage line VSL via a contact hole. The fourth connection electrode BE4 and the fifth connection electrode BE5 may be spaced apart from each other in the second direction DR2. The operation control line ECL or the first upper voltage line VDL′ may be arranged between the fourth connection electrode BE4 and the fifth connection electrode BE5.

The sixth connection electrode BE6 may extend in the first direction DR1 and overlap the first to third pixels PX1, PX2, and PX3. One side of the sixth connection electrode BE6 may be electrically connected to the initialization voltage line VIL via a contact hole. The sixth connection electrode BE6 may be electrically connected to the third gate electrode pattern GP3-1 of each pixel PX1, PX2, or PX3 via a contact hole. The sixth connection electrode BE6 may electrically connect the initialization voltage line VIL to the third transistor T3. The sixth connection electrode BE6 may be arranged to avoid overlapping light-emitting areas EA1, EA2, and EA3 of the respective pixels PX1, PX2, and PX3.

The seventh connection electrode BE7 may have an isolated shape and may have a selected length in the second direction DR2. The seventh connection electrode BE7 may entirely or partially overlap the first voltage line VDL and may be electrically connected to the first voltage line VDL via a contact hole.

The third conductive layer SP may include a third conductive material. The third conductive material may include a metal, an alloy, a conductive metal oxide, a transparent conductive material, etc. According to some embodiments, the third conductive layer SP may include Ag, an alloy containing Ag, Mo, an alloy containing Mo, Al, an alloy containing Al, AlN, W, WN, Cu, Ni, Cr, CrN, Ti, Ta, Pt, Sc, ITO, IZO, etc. According to some embodiments, the third conductive layer SP may have a multilayer structure including a titanium layer having a thickness of 700 Å, an aluminum layer having a thickness of 6000 Å, and a titanium layer having a thickness of 300 Å. This third conductive layer SP may also be called as a source/drain layer.

A first insulating layer 117 may cover the third conductive layer SP and may be positioned on the interlayer insulating layer 115. The first insulating layer 117 may include an insulating material. According to some embodiments, the gate insulating layer 113 may include an inorganic insulating material such as silicon oxide, silicon nitride, silicon oxynitride, aluminum oxide, etc. The first insulating layer 117 may include a material having superior bonding strength with the third conductive layer SP over a second insulating layer 118 described later.

A through hole OP3 exposing a portion of the source electrode 230 or the drain electrode 240 may be formed in the first insulating layer 117. The through hole OP3 may overlap the second contact hole CNT2 of the source electrode 230, but embodiments according to the present disclosure are not limited thereto.

The second insulating layer 118 may be located on the first insulating layer 117. The second insulating layer 118 may include an insulating material that is different from that of the first insulating layer 117. According to some embodiments, the second insulating layer 118 may include an organic insulating material. As a specific example, the second insulating layer 118 may include a photoresist, benzocyclobutene (BCB), polyimide, hexamethyldisiloxane (HMDSO), polymethylmethacrylate (PMMA), polystyrene, a polymer derivative having a phenol group, an acrylic polymer, an imide polymer, an aryl ether polymer, an amide polymer, a fluorinated polymer, a p-xylene polymer, a vinyl alcohol polymer, a mixture thereof, etc. According to some embodiments, a planarization layer 107 may include a polyimide layer having a thickness of 1.6 micrometers (μm) (or approximately 1.6 μm).

A first via hole OP1 and a second via hole OP2 spaced apart from each other can be formed in the second insulating layer 118. The first via hole OP1 may be arranged to overlap the through hole OP3 of the first insulating layer 117 and may expose a portion of the source electrode 230 or the drain electrode 240 of the thin-film transistor TFT.

A width W1 of the first via hole OP1 may be equal to or less than a width W3 of the through hole OP3. In this way, the first via hole OP1 may expose a portion of the source electrode 230 or the drain electrode 240 of the thin-film transistor TFT without exposing the second insulating layer 118. However, the present invention is not limited thereto, and the width W1 of the first via hole OP1 may be formed to be larger than the width W3 of the through hole OP3 such that the first via hole OP1 may expose a portion of the second insulating layer 118. In this case, the width W1 of the first via hole OP1 may have a value selected within a range not exceeding twice the width W3 of the through hole OP3.

The through hole OP3 and the first via hole OP1 may be formed for each pixel PX1, PX2, or PX3 and may serve to connect a pixel electrode 310 of each pixel to the source electrode 230 or drain electrode 240 of the thin-film transistor TFT.

As shown in FIG. 5, in case that the width W1 of the first via hole OP1 is formed small enough to correspond to the size of the width W3 of the through hole OP3, an edge of the first via hole OP1 and an edge of the through hole OP3 may overlap each other or may be excessively close to each other, making it difficult to recognize the edge of the first via hole OP1 with a measuring device.

In contrast, according to embodiments of the present disclosure, the second via hole OP2 spaced apart from the first via hole OP1 to facilitate measurement with a measuring device may be formed in the second insulating layer 118, thereby obtaining a measurement result corresponding to a measurement value of the first via hole OP1 through the second via hole OP2.

The second via hole OP2 may not overlap the through hole OP3 of the first insulating layer 117. The second via hole OP2 may expose a top surface of the first insulating layer 117 by not overlapping the through hole OP3. A width W2 of the second via hole OP2 may be equal to the width W1 of the first via hole OP1, but embodiments according to the present disclosure are not limited thereto.

The second via hole OP2 may be generated by a photoresist process using the same mask as the first via hole OP1. As the second via hole OP2 undergoes the same photoresist process as the first via hole OP1, the second via hole OP2 may include a process error in the same range as the first via hole OP1. As a result, even in case that the width W2 of the second via hole OP2 is formed differently from the width W1 of the first via hole OP1, it is possible to accurately estimate the measurement value of the first via hole OP1 from a measurement value of the second via hole OP2. However, to improve the design freedom of the display device 1, the width W2 of the second via hole OP2 may be formed equal to the width W1 of the first via hole OP1 or less than the width W1 of the first via hole OP1.

A position of the second via hole OP2 may not be particularly limited as long as the second via hole OP2 does not overlap the through hole OP3. According to some embodiments, the second via hole OP2 may be arranged to overlap the first voltage line VDL, the second voltage line VSL, or the initialization voltage line VIL constituting the first conductive layer for convenience of measurement. As another example, the second via hole OP2 may be arranged to overlap the sixth connection electrode BE6 constituting the third conductive layer SP such that the second via hole OP2 may not overlap a light-emitting area of each pixel.

According to some embodiments, the second via hole OP2 may be formed to avoid overlapping the pixel electrode 310. In this case, the pixel electrode 310 may not be bent by the second via hole OP2.

The number of second via holes OP2 may not be specifically limited. The second via hole OP2 may be formed as plurality, but embodiments according to the present disclosure are not limited thereto. According to some embodiments, a selected number of second via holes OP2 may be formed for each pixel unit PXU or for each pixel PX. In another example, one second via hole OP2 may be formed in the entire second insulating layer 118 in a process of forming the first via hole OP1 and the second via hole OP2 in the second insulating layer 118.

The light-emitting diode LD may be positioned on the second insulating layer 118. According to some embodiments, the light-emitting diode LD may be an organic light-emitting diode OLED. The light-emitting diode LD may include the pixel electrode 310, an intermediate layer 320 including a light-emitting layer, and a counter electrode 330.

The pixel electrode 310 may be a (semi)light-transmissive electrode or a reflective electrode. According to some embodiments, the pixel electrode 310 may include a reflective layer including Ag, Mg, Al, Pt, Pd, Au, Ni, Nd, Ir, Cr, a compound thereof, etc., and a transparent or semi-transparent electrode layer located on the reflective layer. The transparent or semi-transparent electrode layer may include at least one selected from a group consisting of ITO, IZO, zinc oxide (ZnO), indium oxide (In₂O₃), indium gallium oxide, and aluminum zinc oxide (AZO). According to some embodiments, the pixel electrode 310 may have a three-layer structure of ITO/Ag/ITO.

A pixel-defining film 119 may be placed on the second insulating layer 118. The pixel-defining film 119 may prevent or reduce instances of an arc, etc., occurring at an edge of the pixel electrode 310 by increasing a distance between the edge of the pixel electrode 310 and the counter electrode 330 above the pixel electrode 310. The pixel-defining film 119 may be formed of one or more organic insulation materials selected from a group of consisting of polyimide, polyamide, acrylic resin, benzocyclobutene, and phenolic resin, by using a method such as spin coating, etc.

At least a portion of the intermediate layer 320 of the light-emitting diode LD may be positioned within an opening formed by the pixel-defining film 119. A light-emitting area EA of the light-emitting diode LD may be defined by the opening.

The intermediate layer 320 may include a light-emitting layer. The light-emitting layer may include an organic material including a fluorescent or phosphorescent material that emits red, green, blue, or white light. The light-emitting layer may be a low-molecular organic material or a high-molecular organic material, and functional layers such as a hole transport layer (HTL), a hole injection layer (HIL), an electron transport layer (ETL), an electron injection layer (EIL), etc., may be selectively arranged below and above the light-emitting layer.

The light-emitting layer may have a patterned shape corresponding to each of the pixel electrodes 310. Layers other than the light-emitting layer, included in the intermediate layer 320, may be modified in various ways, such as being integrally formed across the plurality of pixel electrodes 310.

The counter electrode 330 may be a light-transmissive electrode or a reflective electrode. According to some embodiments, the counter electrode 330 may be a transparent or semitransparent electrode and may include a metal thin film having a small work function, including Li, Ca, LiF, Al, Ag, Mg, and a compound thereof. The counter electrode 330 may further include a transparent conductive oxide (TCO) film such as ITO, IZO, ZnO or In₂O₃ positioned on the metal thin film. The counter electrode 330 may be formed integrally over the entire display area DA and placed on top of the intermediate layer 320 and the pixel-defining film 119.

Embodiments of the present disclosure may enable precise control of the formation of the first via hole OP1 while forming the second via hole OP2 smaller than the first via hole OP1, by simultaneously forming the second via hole OP2 spaced apart from the first via hole OP1 and not overlapping the through hole OP3 in a process of forming the first via hole OP1. Embodiments of the present disclosure may improve an aperture ratio of the light-emitting area EA of each pixel PX by reducing an aperture ratio of the first via hole OP1. Embodiments of the present disclosure may improve the design freedom of the display device 1 by enabling accurate measurement while forming the first via hole OP1 small.

Hereinafter, a method of manufacturing a display device according to some embodiments of the present disclosure will be described, and any description overlapping the foregoing description will be omitted.

On the substrate SUB, the lower metal layer BML may be formed. The lower metal layer BML may be formed by applying a first conductive material on the substrate SUB and then patterning the first voltage line VDL, the second voltage line VSL, the initialization voltage line VIL, and the data line DTL, included in the lower metal layer BML. The lower metal layer BML may be formed by photolithography, and embodiments according to the present disclosure are not limited thereto.

The buffer layer 111 may be formed to cover the lower metal layer BML on the substrate SUB, and then the semiconductor layer 210 may be formed on the buffer layer 111. The semiconductor layer 210 may be formed by forming a silicon layer 134 on the buffer layer 111 and then etching the silicon layer 134 using photolithography, etc.

The gate insulating layer 113 may be formed on the semiconductor layer 210, and the gate electrode 220 may be formed on the gate insulating layer 113. The gate electrode 220 may be formed by applying a second conductive material on the substrate SUB and then patterning the plurality of gate electrode patterns GP that partially overlap the semiconductor layer 210.

Ions may be partially injected into the semiconductor layer 210 to form a source region and a drain region. A portion of the semiconductor layer 210, which overlaps the gate electrode 220, may remain undoped with ions, thereby forming an active region. The active region may be formed between the source region and the drain region, and the ions may be n-type impurities or p-type impurities. A portion of the semiconductor layer 210, doped with ions, may have an increasing conductivity and thus have the properties of a conductor, thereby allowing the source region and the drain region to be formed.

The interlayer insulating layer 115 may be formed on the gate electrode 220. The interlayer insulating layer 115 may be formed to cover all of the buffer layer 111, the semiconductor layer 210, and the gate electrode 220. The interlayer insulating layer 115 may insulate the source electrode 230 and the drain electrode 240 from the gate electrode 220.

The first contact hole CNT1, the second contact hole CNT2, and the third contact hole CNT3 may be respectively formed by etching portions of the interlayer insulating layer 115 and the buffer layer 111. The second contact hole CNT2 may expose the source region of the semiconductor layer 210, and the third contact hole CNT3 may expose the drain region of the semiconductor layer 210.

The source electrode 230 and the drain electrode 240 may be formed on the interlayer insulating layer 115. The source electrode 230 may be connected to the source region of the semiconductor layer 210, and the drain electrode 240 may be connected to the drain region of the semiconductor layer 210. Each of the source electrode 230 and the drain electrode 240 may include a third conductive material. The semiconductor layer 210, the gate electrode 220, the source electrode 230, and the drain electrode 240 may form a thin-film transistor TFT.

The first insulating layer 117 may be formed on the source electrode 230 and the drain electrode 240. The first insulating layer 117 may be formed by applying an inorganic insulating material on the interlayer insulating layer 115 and then etching the through hole OP3 using a first mask. The through hole OP3 may expose a portion of the source electrode 230 or the drain electrode 240.

The second insulating layer 118 may be formed on the first insulating layer 117. The second insulating layer 118 may be formed by applying an organic insulating material on the first insulating layer 117 and then etching the first via hole OP1 and the second via hole OP2 using a second mask. The first via hole OP1 may overlap the through hole OP3, and the second via hole OP2 may not overlap the through hole OP3.

The pixel electrode 310 may be in contact with the source electrode 230 or the drain electrode 240 via the through hole OP3 formed by removing a portion of the first insulating layer 117 and the first via hole OP1 formed by removing a portion of the second insulating layer 118.

The pixel-defining film 119 may be formed on the second insulating layer 118, and the intermediate layer 320 may be formed on the pixel electrode 310. An opening that exposes a portion of the pixel electrode 310 may be formed in the pixel-defining film 119. The counter electrode 330 may be formed on the intermediate layer 320 and the pixel-defining film 119. The counter electrode 330 may include a common electrode of the display device 1. The pixel electrode 310, the intermediate layer 320, and the counter electrode 330 may form the light-emitting diode LD. The light-emitting diode LD may emit light based on driving current transmitted from the thin-film transistor TFT.

The display device 1 according to some embodiments may be applied to various electronic devices. The electronic device according to some embodiments may include the display device 1 described above, and may further include a module or device having additional functions in addition to the display device 1.

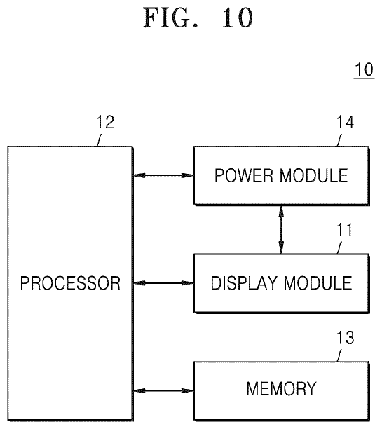

FIG. 10 is a block diagram of an electronic device 10 according to some embodiments of the present disclosure.

Referring to FIG. 10, the electronic device 10 according to some embodiments may include a display module 11, a processor 12, a memory 13, and a power module 14.

The processor 12 may include at least one of a central processing unit (CPU), an application processor AP, a graphic processing unit (GPU), a communication processor (CP), an image signal processor (ISP), or a controller.

The memory 13 may store data information necessary for the operation of the processor 12 or the display module 11. In case that the processor 12 executes an application stored in the memory 13, an image data signal and/or an input control signal may be transmitted to the display module 11, and the display module 11 may process the received signal and output the image information through a display screen.

The power module 14 may include a power supply module, such as a power adapter, a battery device, etc., and a power conversion module that converts power supplied by the power supply module to generate power required for the operation of the electronic device 10.

At least one of the components of the electronic device 10 may be included in the display device according to the above-described embodiments. Some of the individual modules functionally included in a module may be included in the display device and others may be provided separately from the display device. According to some embodiments, the display device may include the display module 11, and the processor 12, the memory 13, and the power module 14 may be provided in the form of other devices in the electronic device 10 other than the display device.

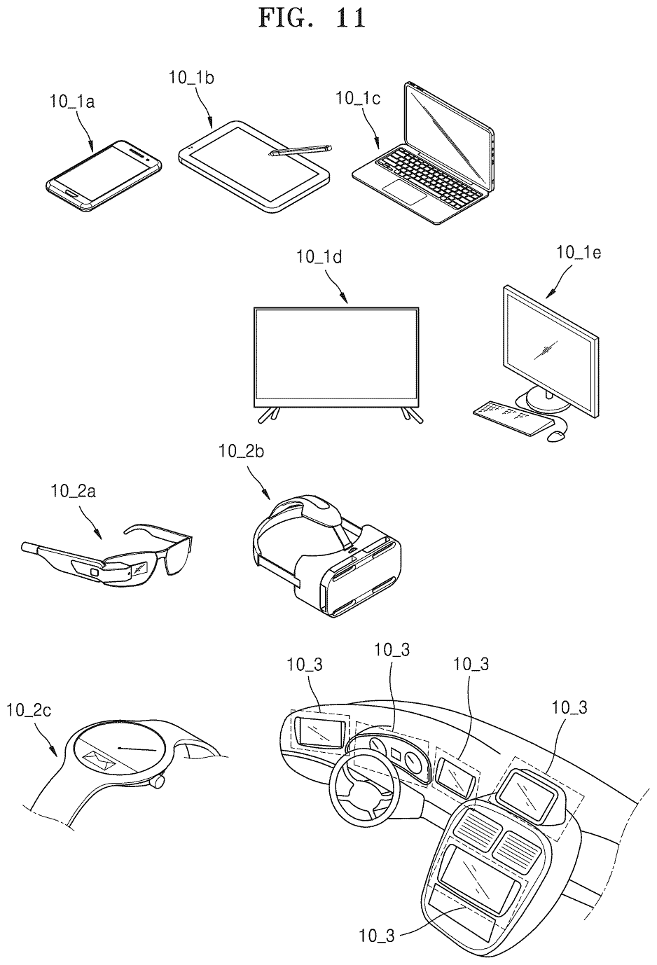

FIG. 11 show schematic diagrams of an electronic device according to various embodiments.

Referring to FIG. 11, various electronic devices to which the display device according to embodiments is applied may include not only image display electronic devices such as a smart phone 10_1a, a tablet PC 10_1b, a laptop computer 10_1c, a TV 10_1d, a desk monitor 10_1e, etc., but also wearable electronic devices including display modules such as smart glasses 10_2a, a head mounted display 10_2b, a smart watch 10_2c, etc., and vehicle electronic devices 10_3 including display modules such as an instrument panel, a center fascia, a center information display (CID) arranged on a dashboard, a room mirror display, etc., of vehicles.

The display device and the electronic device according to embodiments of the present disclosure may accurately measure the size of a via hole overlapping a contact hole of an insulating layer, and form the via hole with a smaller size, thereby relatively improving the aperture ratio of a pixel.

Moreover, the method of manufacturing a display device according to embodiments of the present disclosure may reduce a defect rate due to the via hole by accurately measuring the size of the via hole overlapping the contact hole of the insulating layer.

However, the scope of embodiments according to the present disclosure are not limited by the foregoing effects, and may be expanded in various ways without departing from the spirit and scope of embodiments according to the present disclosure.

Although aspects of some embodiments of the present disclosure have been described with reference to aspects of some embodiments as shown in the drawings, it will be understood by those of ordinary skill in the art that various modifications and changes of embodiments may be made therein without departing from the spirit and scope of embodiments according to the present disclosure. Accordingly, the true technical scope of embodiments according to the present disclosure should be defined by the technical spirit of the appended claims, and their equivalents.

What is claimed is:

1. A display device comprising:
a substrate comprising a display area;
a thin-film transistor on the display area;
a first insulating layer on the thin-film transistor and comprising a through hole exposing a source electrode or a drain electrode of the thin-film transistor;
a second insulating layer on the first insulating layer and comprising a first via hole and a second via hole which are spaced apart from each other; and
a pixel electrode on the second insulating layer and electrically connected to the thin-film transistor via the through hole,
wherein the first via hole overlaps the through hole, and the second via hole does not overlap the through hole.

2. The display device of claim 1, further comprising an initialization voltage line extending in a first direction on the substrate,
wherein the second via hole overlaps the initialization voltage line.

3. The display device of claim 1, wherein the second via hole does not overlap the pixel electrode.

4. The display device of claim 1, wherein the second via hole does not overlap the source electrode or the drain electrode exposed by the through hole.

5. The display device of claim 1, wherein a width of the second via hole is less than or equal to a width of the first via hole.

6. The display device of claim 1, wherein a width of the first via hole is less than or equal to a width of the through hole.

7. The display device of claim 1, wherein a width of the first via hole is at most twice a width of the through hole.

8. The display device of claim 1, wherein the source electrode or the drain electrode of the thin-film transistor comprises copper (Cu).

9. The display device of claim 1, wherein the second via hole exposes a portion of the first insulating layer.

10. The display device of claim 1, wherein the second via hole is formed as plurality.

11. A method of manufacturing a display device, the method comprising:
forming, on a display area of a substrate, a thin-film transistor comprising a source electrode and a drain electrode;
forming, on the thin-film transistor, a first insulating layer comprising a through hole exposing the source electrode or the drain electrode;
forming, on the first insulating layer, a second insulating layer comprising a first via hole and a second via hole; and
forming, on the second insulating layer, a pixel electrode electrically connected to the source electrode or the drain electrode via the through hole,
wherein the first via hole overlaps the through hole, and the second via hole does not overlap the through hole.

12. The method of claim 11, further comprising forming an initialization voltage line extending in a first direction on the substrate,
wherein the second via hole overlaps the initialization voltage line.

13. The method of claim 11, wherein the second via hole does not overlap the pixel electrode.

14. The method of claim 11, wherein a width of the second via hole is less than or equal to a width of the first via hole.

15. The method of claim 11, wherein a width of the first via hole is less than or equal to a width of the through hole.

16. The method of claim 11, wherein a width of the first via hole is at most twice a width of the through hole.

17. The method of claim 11, wherein the source electrode or the drain electrode of the thin-film transistor comprises copper (Cu).

18. The method of claim 11, wherein the second via hole exposes a portion of the first insulating layer.

19. The method of claim 11, wherein the second via hole is formed as plurality.

20. An electronic device comprising:
a processor configured to generate a scan input signal;
a power module configured to generate a scan input voltage; and
a display device configured to receive the scan input signal and the scan input voltage and output a scan signal to a pixel circuit,
wherein the display device comprises:
a substrate comprising a display area;
a thin-film transistor on the display area;
a first insulating layer on the thin-film transistor and comprising a through hole exposing a source electrode or a drain electrode of the thin-film transistor;
a second insulating layer on the first insulating layer and comprising a first via hole and a second via hole which are spaced apart from each other; and
a pixel electrode on the second insulating layer and electrically connected to the thin-film transistor via the through hole, and
wherein the first via hole overlaps the through hole, and the second via hole does not overlap the through hole.
